(19) United States
(12) Patent Application Publication
(10) Pub. No.: US 2024/0322012 A1
(43) Pub. Date: Sep. 26, 2024

(54) SEMICONDUCTOR DEVICE

(71) Applicant: SAMSUNG ELECTRONICS CO., LTD., Suwon-si (KR)

(72) Inventors: Byeonghee Son, Suwon-si (KR); Myunggil Kang, Suwon-si (KR); Dongwon Kim, Suwon-si (KR); Jongsu Kim, Suwon-si (KR); Changwoo Noh, Suwon-si (KR); Beomjin Park, Suwon-si (KR)

(21) Appl. No.: 18/602,274

(22) Filed: Mar. 12, 2024

(30) Foreign Application Priority Data
Mar. 24, 2023 (KR) 10-2023-0038955
Apr. 18, 2023 (KR) 10-2023-0050937

(51) Int. Cl. H01L 29/66; H01L 29/06; H01L 29/423; H01L 29/775; H01L 29/786

(52) U.S. Cl. CPC H01L 29/66553; H01L 29/0673; H01L 29/42392; H01L 29/66439; H01L 29/775; H01L 29/78696

(57) ABSTRACT

A semiconductor device including an active region extending in a first horizontal direction, a nanosheet stack apart from the active region, a plurality of gate structures extending in a second horizontal direction and including a plurality of gate electrodes, a plurality of source/drain regions arranged on sidewalls of the gate structures, and a device isolation layer extending in a vertical direction, wherein the plurality of gate structures include a first gate structure in which a source/drain region is arranged on one sidewall and the device isolation layer is arranged on the other sidewall, and a second gate structure in which source/drain regions are arranged on both sidewalls, wherein the plurality of gate electrodes of the first gate structure include a main gate electrode positioned at the uppermost end and a plurality of sub-gate electrodes, and an internal spacer is between the device isolation layer and the plurality of sub-gate electrodes.

### CROSS-REFERENCE TO RELATED APPLICATION

This application is based on and claims priority under 35 U.S.C. § 119 to Korean Patent Application Nos. 10-2023-0038955, filed on Mar. 24, 2023, and 10-2023-0050937, filed on Apr. 18, 2023, in the Korean Intellectual Property Office, the disclosures of which are incorporated by reference herein in their entireties.

### BACKGROUND

### 1. Field

Embodiments relate to a semiconductor device, and more particularly, a semiconductor device including a field effect transistor (FET).

### 2. Description of the Related Art

Due to the development of electronic technology, demands for high integration of integrated circuit devices are increasing and downscaling is in progress. Due to downscaling of the integrated circuit device, the short channel effect of a transistor occurs, thereby reducing reliability of the integrated circuit device. In order to reduce the short-channel effect, an integrated circuit device having a multi-gate structure such as a nanosheet type transistor has been proposed.

### SUMMARY

Embodiments are directed to a semiconductor device, including a substrate, an active region protruding from the substrate and extending in a first horizontal direction, a nanosheet stack spaced apart from a top surface of the active region and having a channel region, a plurality of gate structures extending in a second horizontal direction perpendicular to the first horizontal direction on the active region and including a plurality of gate electrodes surrounding the nanosheet stack, respectively, a plurality of source/drain regions arranged on sidewalls of the plurality of gate structures on the active region and contacting the nanosheet stack, and a device isolation layer passing through the nanosheet stack and extending in a vertical direction perpendicular to the first horizontal direction and the second horizontal direction, wherein the plurality of gate structures include a first gate structure in which a source/drain region is arranged on one sidewall of the first gate structure and the device isolation layer is arranged on another sidewall opposite the one sidewall of the first gate structure, and a second gate structure in which source/drain regions are arranged on both sidewalls of the second gate structure, the plurality of gate electrodes of the first gate structure include a main gate electrode positioned at an uppermost end and a plurality of sub-gate electrodes in the nanosheet stack, and an internal spacer is between the device isolation layer and at least one of the plurality of sub-gate electrodes.

Embodiments are directed to a semiconductor device, including a substrate, an active region protruding from the substrate and extending in a first horizontal direction, a nanosheet stack spaced apart from a top surface of the active region and including a plurality of nanosheets functioning as a channel region, a plurality of gate structures extending in a second horizontal direction perpendicular to the first horizontal direction on the active region and including a plurality of gate electrodes surrounding the nanosheet stack, respectively, a plurality of source/drain regions arranged on sidewalls of the plurality of gate structures on the active region and contacting the nanosheet stack, and a device isolation layer passing through the nanosheet stack and extending in a vertical direction perpendicular to the first horizontal direction and the second horizontal direction, wherein the plurality of gate structures include a first gate structure in which a source/drain region is arranged on one sidewall and the device isolation layer is arranged on another sidewall opposite the one sidewall, and a second gate structure in which source/drain regions are arranged on both sidewalls of the second gate structure, the plurality of gate electrodes of the first gate structure include a main gate electrode positioned at an uppermost end, a plurality of sub-gate electrodes in the nanosheet stack, and a first connection gate electrode connecting the main gate electrode to a third sub-gate electrode positioned at the uppermost end of the plurality of sub-gate electrodes, and an internal spacer is between the device isolation layer and a first sub-gate electrode positioned at a lowermost end of the plurality of sub-gate electrodes.

Embodiments are directed to a semiconductor device, including a substrate having a fin-type active region extending in a first horizontal direction, a nanosheet stack apart from a top surface of the active region and including a plurality of nanosheets functioning as a channel region, a plurality of gate structures extending in a second horizontal direction perpendicular to the first horizontal direction on the active region and including a plurality of gate electrodes surrounding the nanosheet stack, respectively, a plurality of source/drain regions arranged on sidewalls of the plurality of gate structures on the active region and contacting the nanosheet stack, a device isolation layer passing through the nanosheet stack and extending in a vertical direction perpendicular to the first horizontal direction and the second horizontal direction, an inter-gate insulating layer arranged on the plurality of source/drain regions, and a plurality of source/drain contacts extending through the inter-gate insulating layer and connected to the plurality of source/drain regions, respectively, wherein the plurality of gate structures include a first gate structure in which a source/drain region is arranged on one sidewall and the device isolation layer is arranged on another sidewall opposite the one sidewall, and a second gate structure in which source/drain regions are arranged on both sidewalls of the second gate structure, the plurality of gate electrodes of the first gate structure include a main gate electrode positioned at an uppermost end and a plurality of sub-gate electrodes in the nanosheet stack, and an internal spacer is between the device isolation layer and at least one of the plurality of sub-gate electrodes, between the first gate structure and the source/drain region arranged on one sidewall of the first gate structure, and between the second gate structure and the source/drain regions arranged on both sidewalls of the second gate structure.

### BRIEF DESCRIPTION OF THE DRAWINGS

Features will become apparent to those of skill in the art by describing in detail exemplary embodiments with reference to the attached drawings in which:

FIG. 1 shows a cross-sectional view of a semiconductor device according to embodiments;

FIG. 2 shows an enlarged cross-sectional view of the portion EX1 of FIG. 1;

FIG. 3 shows an enlarged cross-sectional view of a portion corresponding to the portion EX1 of FIG. 1;

FIG. 4 shows an enlarged cross-sectional view of a portion corresponding to the portion EX1 of FIG. 1;

FIG. 5 shows a cross-sectional view of a semiconductor device according to embodiments;

FIG. 6 shows an enlarged cross-sectional view of the portion EX2 of FIG. 5;

FIG. 7 shows a cross-sectional view of a semiconductor device according to embodiments;

FIG. 8 shows an enlarged cross-sectional view of the portion EX3 of FIG. 7; and

FIGS. 9A to 9J show cross-sectional views of stages in a method of manufacturing a semiconductor device according to embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements, and their repetitive descriptions are omitted.

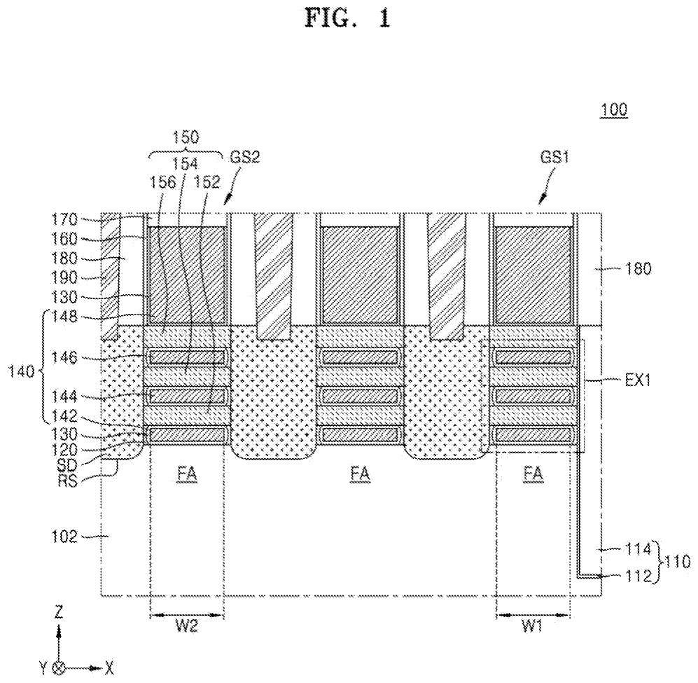

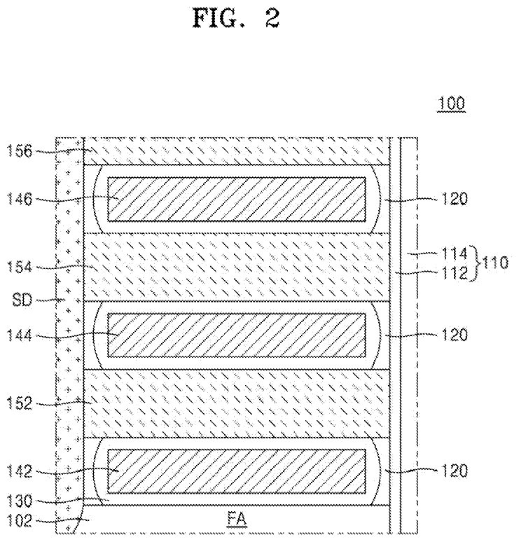

FIG. 1 shows a cross-sectional view of a semiconductor device 100 according to embodiments. FIG. 2 shows an enlarged cross-sectional view of the portion EX1 of FIG. 1.

Referring to FIGS. 1 and 2, the semiconductor device 100 may include a substrate 102, nanosheet stacks 150 arranged on the substrate 102, first and second gate structures GS1 and GS2 arranged on the substrate 102, a plurality of source/drain regions SD contacting the nanosheet stacks 150, and source/drain contacts 190 connected to the plurality of source/drain regions SD.

The semiconductor device 100 shown in FIGS. 1 and 2 may include a multi-bridge channel FET (MBCFET) device. However, the semiconductor device 100 may include a planar FET device, a gate-all-around (GAA) type FET device, and a finFET device.

The substrate 102 may include a plurality of active regions FA. Each of the plurality of active regions FA may have a fin structure protruding from the substrate 102 and extending in a first horizontal direction (X direction).

The substrate 102 may include a group IV semiconductor such as silicon (Si) or germanium (Ge), a group IV-IV compound semiconductor such as silicon-germanium (SiGe) or silicon carbide (SiC), or a group III-V compound semiconductor such as gallium arsenide (GaAs), indium arsenide (InAs), or indium phosphide (InP). The terms “SiGe”, “SiC”, “GaAs”, “InAs”, and “InP” used in the current specification refer to materials formed of elements included therein, and are not chemical formulas representing stoichiometric relationships. The substrate 102 may include a conductive region, e.g., a well doped with impurities or a structure doped with impurities.

On the plurality of active regions FA, a plurality of gate electrodes 140 may extend in a second horizontal direction (Y direction) intersecting with the first horizontal direction (the X direction). In regions in which the plurality of active regions FA intersect with the plurality of gate electrodes 140, the nanosheet stacks 150 may be apart from top surfaces of the plurality of active regions FA in the vertical direction (Z direction) perpendicular to the first horizontal direction and the second horizontal direction. The term “nanosheet” used in the current specification refers to a conductive structure having a cross-section substantially perpendicular to a direction in which a current flows. It should be understood that the nanosheet may include nanowires.

Each of the nanosheet stacks 150 may include first to third nanosheets 152, 154, and 156 overlapping from the top surface of each of the plurality of active regions FA in the vertical direction (the Z direction). The first to third nanosheets 152, 154, and 156 may have different vertical distances (distances in the Z direction) from the top surface of each of the plurality of active regions FA. The first to third nanosheets 152, 154, and 156 may be sequentially stacked on the top surface of each of the plurality of active regions FA. Each of the first to third nanosheets 152, 154, and 156 may include a group IV semiconductor such as Si or Ge, a group IV-IV compound semiconductor such as SiGe or SiC, or a group III-V compound semiconductor such as GaAs, InAs, or InP.

In an implementation, one or more nanosheet stacks 150 and one or more gate electrodes 140 may be arranged on each of the plurality of active regions FA.

In FIGS. 1 and 2, it is shown that each of the nanosheet stacks 150 may include three nanosheets, e.g., the first to third nanosheets 152, 154, and 156. In an implementation, each of the nanosheet stacks 150 may include one or more nanosheets. Each of the first to third nanosheets 152, 154, and 156 may include a channel region. In embodiments, the first to third nanosheets 152, 154, and 156 may have substantially the same thickness in the vertical direction (the Z direction). In other embodiments, at least some of the first to third nanosheets 152, 154, and 156 may have different thicknesses in the vertical direction (the Z direction).

As shown in FIGS. 1 and 2, the first to third nanosheets 152, 154, and 156 included in each of the nanosheet stacks 150 may have the same size in the first horizontal direction (the X direction). In other embodiments, at least some of the first to third nanosheets 152, 154, and 156 included in each of the nanosheet stacks 150 may have different sizes in the first horizontal direction (the X direction). In an implementation, in the first horizontal direction (the X direction), a length of each of the first nanosheet 152 and the second nanosheet 154 close to the top surface of each of the plurality of active regions FA among the first to third nanosheets 152, 154, and 156 may be less than a length of the third nanosheet 156 farthest from the top surface of each of the plurality of active regions FA.

A device isolation layer 110 may extend through parts of the nanosheet stack 150 and the substrate 102. The device isolation layer 110 may include an insulating liner 112 conformally covering an internal wall of a trench in which the device isolation layer 110 may be arranged, and a gap fill insulating layer 114 filling the trench on the insulating liner 112.

The first gate structure GS1 and the second gate structure GS2 may extend in the second horizontal direction (the Y direction) to surround the nanosheet stacks 150 and may be apart from each other in the first horizontal direction (the X direction). The first gate structure GS1 may be closest to and contact the device isolation layer 110 to be described below, and the second gate structure GS2 may not contact the device isolation layer 110.

Each of the first gate structure GS1 and the second gate structure GS2 may include gate insulating layers 130, the gate electrode 140, a gate spacer 160, and a gate capping layer 170. The gate insulating layers 130, the gate electrode 140, the gate spacer 160, and the gate capping layer 170 included in the first gate structure GS1 may be respectively referred to as first gate insulating layers, a first gate electrode, a first gate spacer, and a first gate capping layer and the gate insulating layers 130, the gate electrode 140, the gate spacer 160, and the gate capping layer 170 included in the second gate structure GS2 may be respectively referred to as second gate insulating layers, a second gate electrode, a second gate spacer, and a second gate capping layer.

The plurality of gate electrodes 140 may extend on the plurality of active regions FA in the second horizontal direction (the Y direction), respectively. Each of the plurality of gate electrodes 140 may cover a nanosheet stack 150 on each of the plurality of active regions FA and may surround the first to third nanosheets 152, 154, and 156.

Each of the plurality of gate electrodes 140 may include a main gate electrode 148 and first to third sub-gate electrodes 142, 144, and 146. The main gate electrode 148 may cover the top surface of each of the nanosheet stacks 150 and may extend in the second horizontal direction (the Y direction). The first to third sub-gate electrodes 142, 144, and 146 may be integrally connected to the main gate electrode 148 and may be arranged among the first to third nanosheets 152, 154, and 156 and between each of the plurality of active regions FA and the first nanosheet 152. The first sub-gate electrode 142 may be closest to the top surface of each of the plurality of active regions FA, the third sub-gate electrode 146 may be farthest from the top surface of each of the plurality of active regions FA, and the second sub-gate electrode 144 may be between the first sub-gate electrode 142 and the third sub-gate electrode 146.

Each of the plurality of gate electrodes 140 may include doped polysilicon, a metal, conductive metal nitride, conductive metal carbide, conductive metal silicide, or a combination thereof. In an implementation, each of the plurality of gate electrodes 140 may include aluminum (Al), copper (Cu), titanium (Ti), tantalum (Ta), tungsten (W), molybdenum (Mo), TaN, NiSi, CoSi, TiN, WN, TiAl, TiAlN, TaCN, TaC, TaSiN, or a combination thereof. In embodiments, each of the plurality of gate electrodes 140 may include a work function metal-containing layer and a gap fill metal layer. The work function metal-containing layer may include at least one metal selected from Ti, W, ruthenium (Ru), niobium (Nb), Mo, hafnium (Hf), nickel (Ni), cobalt (Co), platinum (Pt), ytterbium (Yb), terbium (Tb), dysprosium (Dy), erbium (Er), and palladium (Pd). The gap fill metal layer may include a W layer or an Al layer. In embodiments, each of the plurality of gate electrodes 140 may include a stacked structure of TiAIC/TiN/W, a stacked structure of TiN/TaN/TiAIC/TiN/W, or a stacked structure of TiN/TaN/TiN/TiAlC/TiN/W.

In an embodiment, a first horizontal direction length (an X direction length) W1 of the gate electrode 140 (that is, the first gate electrode) of the first gate structure GS1 may be less than a first horizontal direction length (an X direction length) W2 of the gate electrode 140 (that is, the second gate electrode) of the second gate structure GS2.

The gate insulating layers 130 may be arranged between the gate electrode 140 and the active region FA, between the gate electrode 140 of the first gate structure GS1 and the device isolation layer 110, and between the gate electrode 140 and each of the first to third nanosheets 152, 154, and 156. Each of the gate insulating layers 130 may include a silicon oxide layer, a silicon oxynitride layer, a high dielectric layer having a higher dielectric constant than that of the silicon oxide layer, or a combination thereof. The high dielectric layer may include metal oxide or metal oxynitride. In an implementation, the high dielectric layer may include HfO₂, HfSiO, HfSiON, HfTaO, HfTiO, HfZrO, ZrO₂, Al₂O₃, or a combination thereof.

A top surface of the main gate electrode 148 included in each of the plurality of gate electrodes 140 and a top surface of the gate insulating layer 130 surrounding the main gate electrode 148 may be covered with the gate capping layer 170. The gate capping layer 170 may extend in the second horizontal direction (the Y direction) on the main gate electrode 148 and the gate insulating layer 130 surrounding the main gate electrode 148. In embodiments, the gate capping layer 170 may include silicon nitride or silicon oxynitride.

The gate spacer 160 may be arranged on both sidewalls of the main gate electrode 148 included in each of the plurality of gate electrodes 140 and both sidewalls of the gate capping layer 170. The gate spacer 160 may be apart from the main gate electrode 148 with the gate insulating layer 130 therebetween. In embodiments, the gate spacer 160 may include silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N_{z}), or a combination thereof.

A plurality of recesses RS may be formed in a top surface of the active region FA. Each of the plurality of recesses RS may extend into the active region FA. The plurality of source/drain regions SD may be formed in the plurality of recesses RS, respectively. Each of the plurality of source/drain regions SD may be arranged on one of both sidewalls of the first gate structure GS1 and both sidewalls of the second gate structure GS2. In this case, the device isolation layer 110 may be arranged on the other sidewall of the first gate structure which may be opposite to one sidewall of the first gate structure GS1 where the each of the plurality of source/drain regions SD may be arranged. Each of the plurality of source/drain regions SD may be connected to both ends of each of the nanosheet stacks 150. Each of the plurality of source/drain regions SD may have a vertical cross-sectional shape such as a hexagonal shape, a pentagonal shape, a rhombus shape, or a polygon having rounded corners. In embodiments, each of the plurality of source/drain regions SD may include a doped SiGe layer, a doped Ge layer, a doped SiC layer, or a doped InGaAs layer. In embodiments, the plurality of source/drain regions SD may include a plurality of semiconductor layers having different compositions, respectively. In an implementation, each of the plurality of source/drain regions SD may include a lower semiconductor layer, an upper semiconductor layer, and a capping semiconductor layer sequentially filling each of the plurality of recesses RS. In an implementation, the lower semiconductor layer, the upper semiconductor layer, and the capping semiconductor layer may each include SiC and may have different Si and C contents.

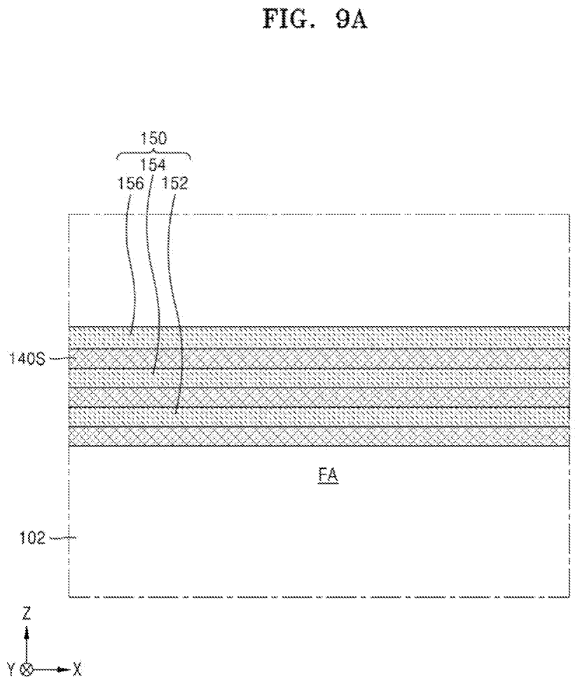

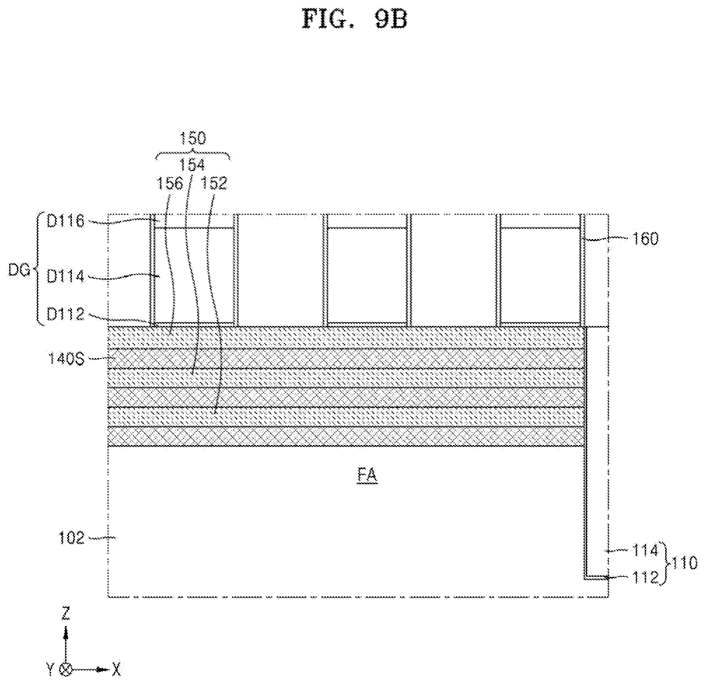

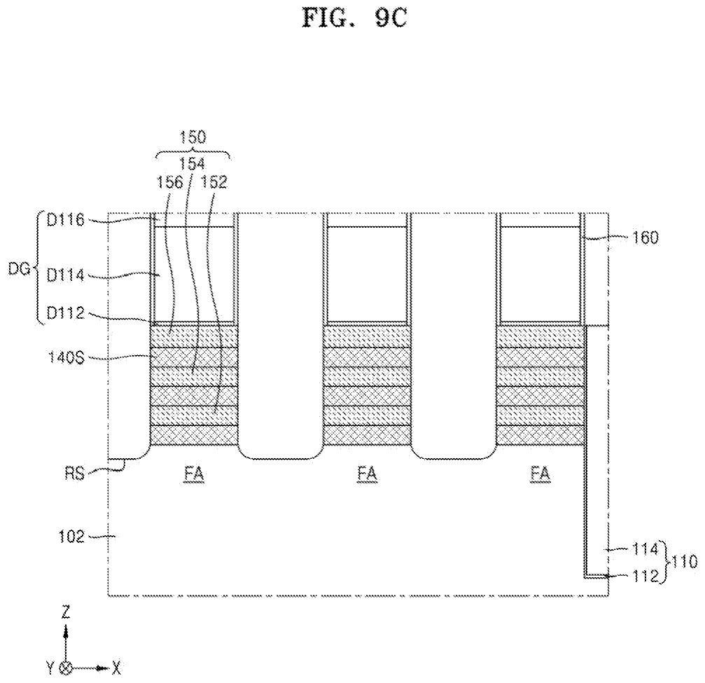

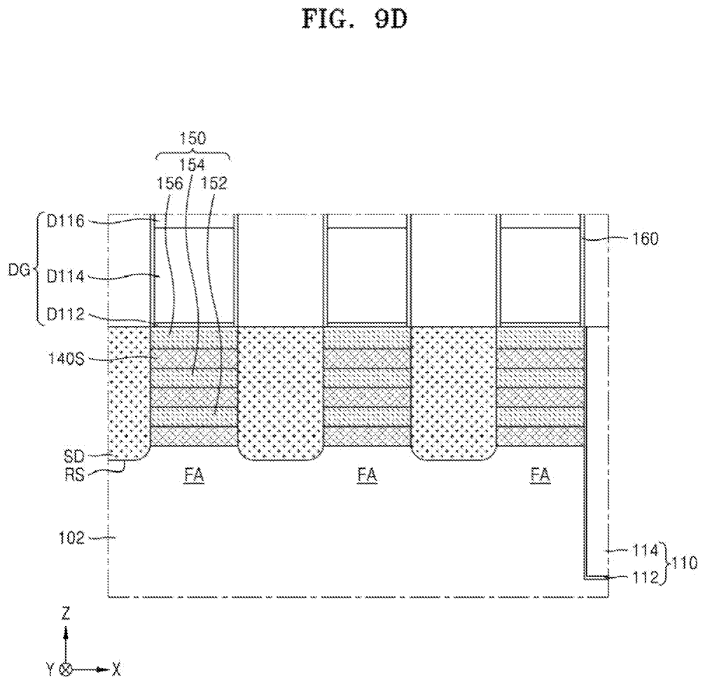

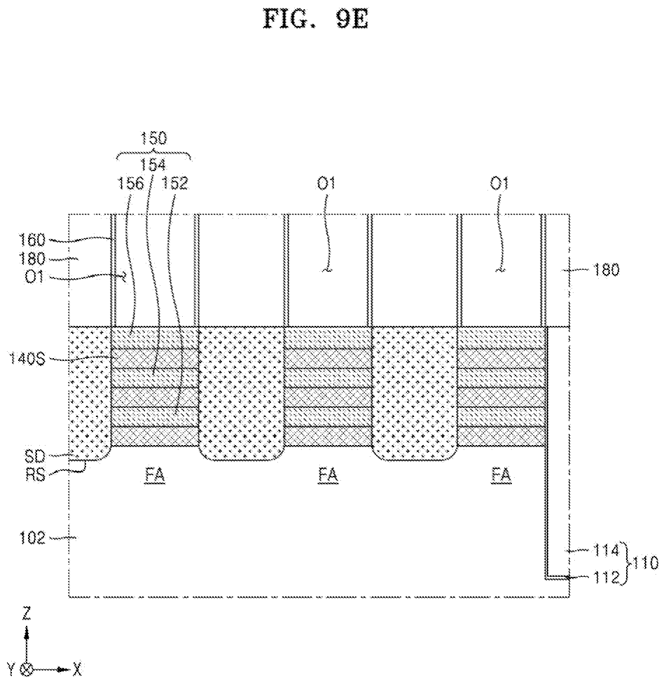

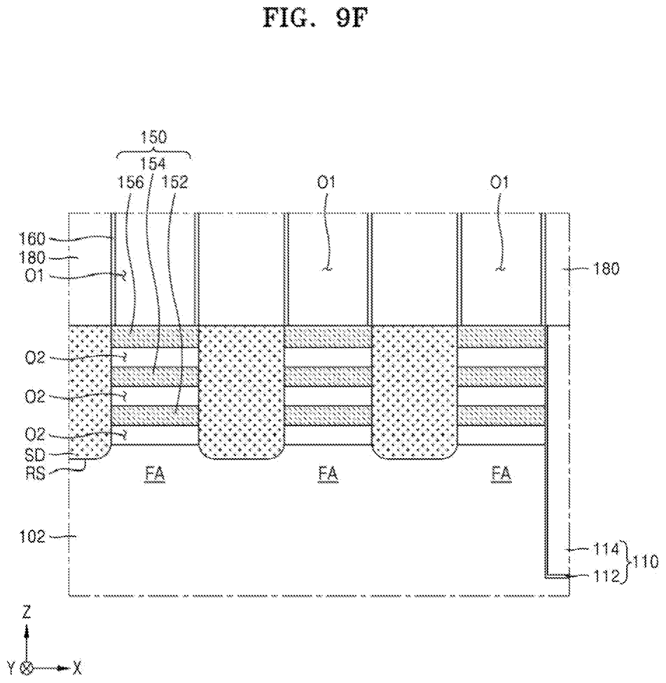

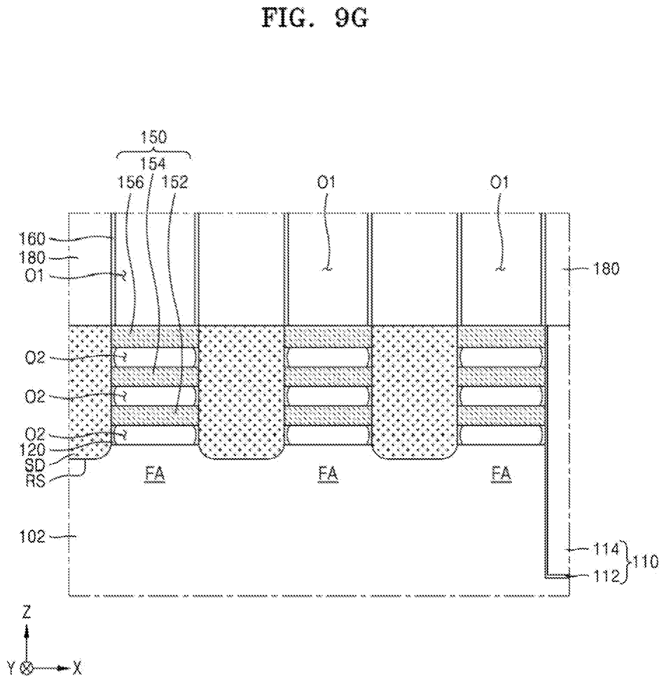

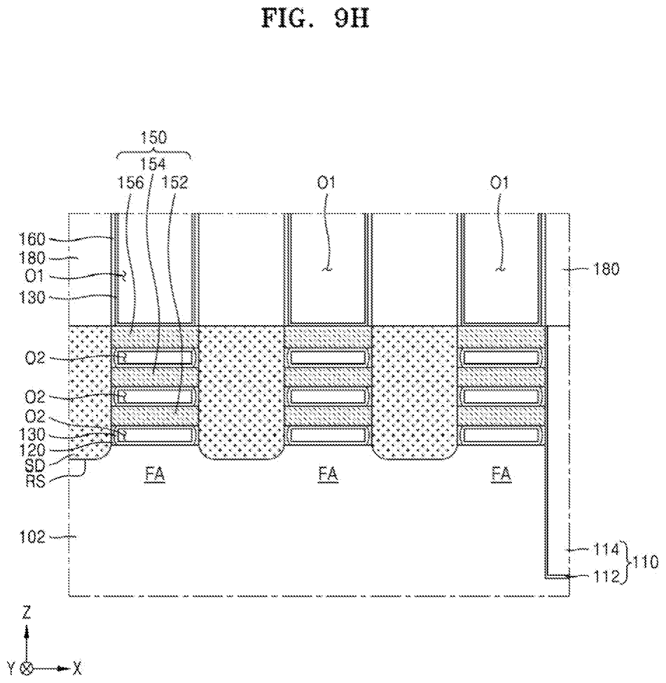

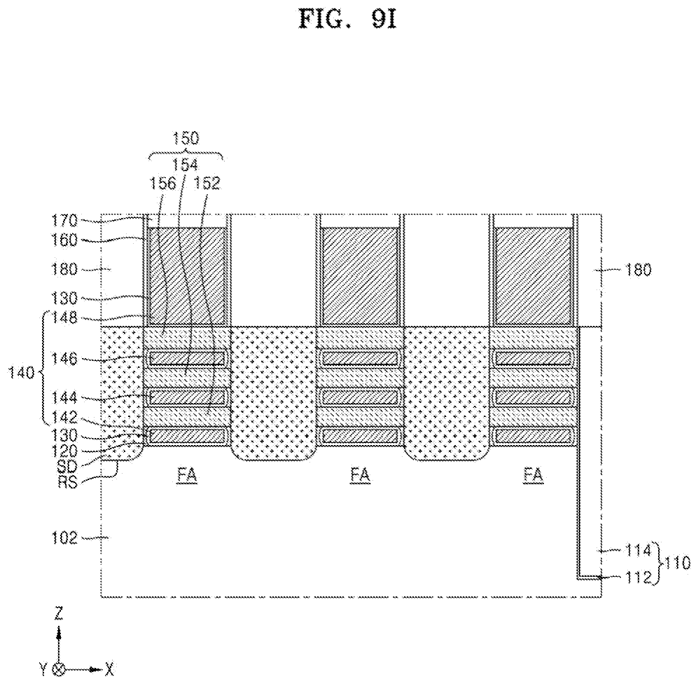

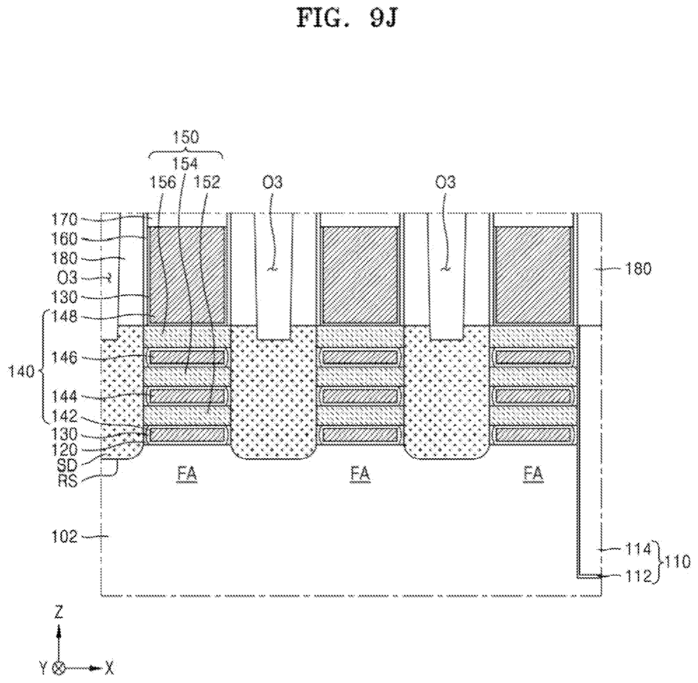

Internal spacers 120 may be between the first to third sub-gate electrodes 142, 144, and 146 and the plurality of source/drain regions SD and between the first to third sub-gate electrodes 142, 144, and 146 and the device isolation layer 110. The internal spacer 120 may be apart from each of the first to third sub-gate electrodes 142, 144, and 146 with the gate insulating layer 130 therebetween. In embodiments, the internal spacer 120 may include silicon oxide (SiOₓ), silicon nitride (SiNₓ), silicon oxynitride (SiOₓN_{y}), silicon carbonitride (SiCₓN_{y}), silicon carbonate (SiOC), silicon oxycarbonitride (SiOₓC_{y}N_{z}), or a combination thereof. In embodiments, the internal spacer 120 may have a convexly rounded shape in an outward direction of each of the first to third sub-gate electrodes 142, 144, and 146. The shape of the internal spacer 120 may be obtained by forming the internal spacers 120 on second openings O2 (refer to FIG. 9F) formed by removing a plurality of sacrificial gate layers 140S (refer to FIG. 9E).

An inter-gate insulating layer 180 may be arranged on the plurality of source/drain regions SD and the device isolation layer 110 between the first and second gate structures GS1 and GS2. In embodiments, the inter-gate insulating layer 180 may include silicon oxide, silicon carbon oxide, or silicon oxynitride.

The source/drain contact 190 may be arranged on each of the plurality of source/drain regions SD. The source/drain contact 190 may extend through the inter-gate insulating layer 180. The source/drain contact 190 may be connected to each of the plurality of source/drain regions SD. A bottom surface of the source/drain contact 190 may be at a lower level than a top surface of each of the plurality of source/drain regions SD. The source/drain contact 190 may include a contact plug and a conductive barrier layer covering the contact plug. The contact plug may include at least one of W, Co, Mo, Ni, Ru, Cu, Al, silicide thereof, and an alloy thereof. The conductive barrier layer may include at least one of Ru, Ti, titanium nitride (TiN), Ta, tantalum nitride (TaN), W, titanium silicon nitride (TiSiN), titanium silicide (TiSi), and tungsten silicide (WSi).

In general, the plurality of recesses RS may be formed in the plurality of sacrificial gate layers 140S (refer to FIG. 9A) exposed by the openings formed by removing parts of the plurality of sacrificial gate layers 140S (refer to FIG. 9A) stacked on the substrate 102 in order to form the plurality of source/drain regions SD and the plurality of recesses RS may be filled with an insulating material to form the internal spacers 120. However, in this case, the internal spacers 120 may not be formed on one sidewall of the first gate structure GS1 adjacent to the device isolation layer 110, in which the openings may not be formed, so that a gate electrode and a gate insulating layer may burst on one sidewall of the first gate structure GS1, in which the internal spacers 120 may not be formed, during semiconductor device manufacturing processes performed after the internal spacers 120 are formed.

On the other hand, in the semiconductor device 100 according to the embodiments, because the internal spacers 120 may be formed in the openings O2 (refer to FIG. 9F) formed by removing the plurality of sacrificial gate layers 140S (refer to FIG. 9A), the internal spacers 120 may also be formed on one sidewall of the first gate structure GS1 adjacent to the device isolation layer 110. Therefore, it may be possible to prevent the gate electrode 140 and the gate insulating layers 130 from bursting on one sidewall of the first gate structure GS1 during the semiconductor device 100 manufacturing processes performed after the internal spacers 120 may be formed.

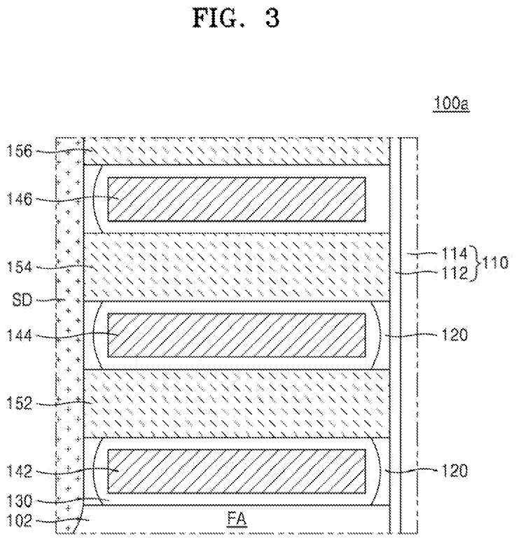

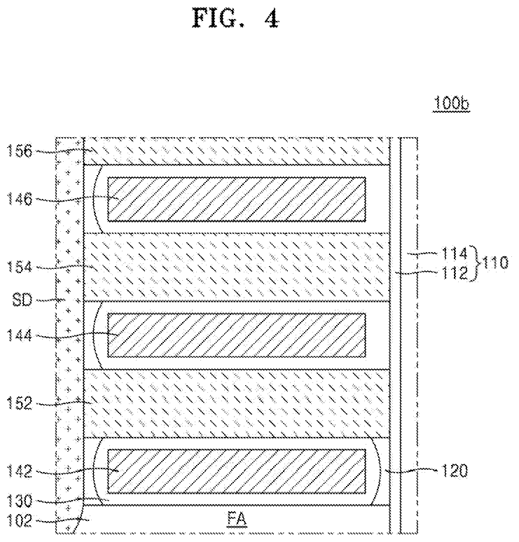

FIG. 3 shows an enlarged cross-sectional view of a portion corresponding to the portion EX1 of FIG. 1. FIG. 4 shows an enlarged cross-sectional view of a portion corresponding to the portion EX1 of FIG. 1. Because configurations of the semiconductor device 100a shown in FIG. 3 and the semiconductor device 100b shown in FIG. 4 are similar to a configuration of the semiconductor device 100 described with reference to FIGS. 1 and 2, the differences therebetween are mainly described hereinafter.

Referring to FIGS. 1 and 3, the internal spacers 120 may be between the first sub-gate electrode 142 and the device isolation layer 110 and between the second sub-gate electrode 144 and the device isolation layer 110, but may not be between the third sub-gate electrode 146 and the device isolation layer 110. Accordingly, the gate insulating layer 130 surrounding the third sub-gate electrode 146 may contact the device isolation layer 110. It is shown in FIG. 3 that the internal spacer 120 is not between the third sub-gate electrode 146 and the device isolation layer 110. In an implementation, the internal spacer 120 may not be between the first sub-gate electrode 142 and the device isolation layer 110 or between the second sub-gate electrode 144 and the device isolation layer 110.

Referring to FIGS. 1 and 4, the internal spacers 120 may be between the first sub-gate electrode 142 and the device isolation layer 110 but may not be between the second sub-gate electrode 144 and the device isolation layer 110 and between the third sub-gate electrode 146 and the device isolation layer 110. Accordingly, the gate insulating layers 130 surrounding the second sub-gate electrode 144 and the third sub-gate electrode 146 may contact the device isolation layer 110. It is shown in FIG. 4 that the internal spacer 120 is only between the first sub-gate electrode 142 and the device isolation layer 110. In an implementation, the internal spacer 120 may be only between the second sub-gate electrode 144 and the device isolation layer 110 or between the third sub-gate electrode 146 and the device isolation layer 110.

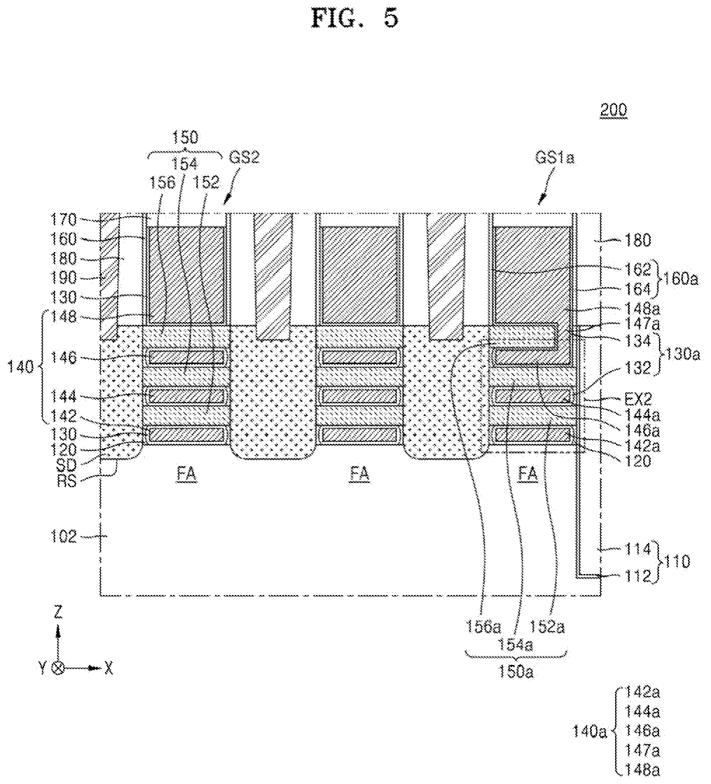

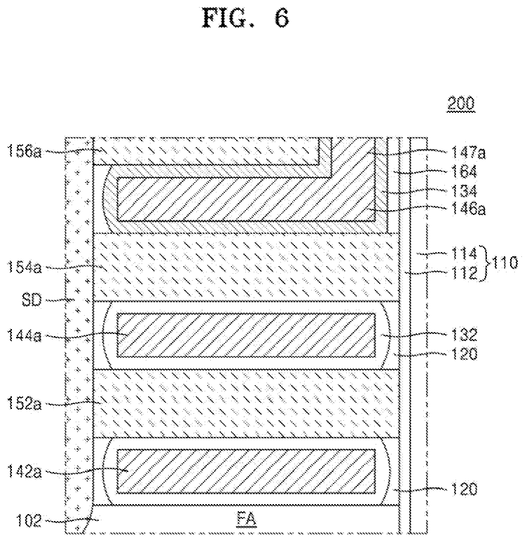

FIG. 5 shows a cross-sectional view of a semiconductor device 200 according to embodiments. FIG. 6 is an enlarged cross-sectional view of the portion EX2 of FIG. 5. Because a configuration of the semiconductor device 200 shown in FIG. 5 is similar to the configuration of the semiconductor device 100 described with reference to FIGS. 1 and FIG. 2, the differences therebetween are mainly described hereinafter.

Referring to FIGS. 5 and 6, the semiconductor device 200 may include a substrate 102, nanosheet stacks 150a arranged on the substrate 102, first and second gate structures GS1a and GS2 arranged on the substrate 102, a plurality of source/drain regions SD contacting the nanosheet stacks 150a, and source/drain contacts 190 connected to the plurality of source/drain regions SD.

The nanosheet stacks 150a may be apart from top surfaces of a plurality of active regions FA in the vertical direction (the Z direction) perpendicular to the first horizontal direction (the X direction) and the second horizontal direction (the Y direction). First to third nanosheets 152a, 154a, and 156a may be sequentially stacked on the top surface of each of the plurality of active regions FA. In embodiments, in the first horizontal direction (the X direction), a length of the third nanosheet 156a may be less than a length of each of the first nanosheet 152a and the second nanosheet 154a.

The first gate structure GS1a may include gate insulating layers 130a, a gate electrode 140a, a gate spacer 160a, and a gate capping layer 170.

The gate electrode 140a may include a main gate electrode 148a, first to third sub-gate electrodes 142a, 144a, and 146a, and a connection gate electrode 147a. The main gate electrode 148a may cover a top surface of the nanosheet stack 150a and may extend in the second horizontal direction (the Y direction). The first to third sub-gate electrodes 142a, 144a, and 146a may be integrally connected to the main gate electrode 148a and may be arranged among the first to third nanosheets 152a, 154a, and 156a and between the active region FA and the first nanosheet 152a. The first sub-gate electrode 142a may be closest to the top surface of the active region FA, the third sub-gate electrode 146a may be farthest from the top surface of the active region FA, and the second sub-gate electrode 144a may be between the first sub-gate electrode 142a and the third sub-gate electrode 146a.

In embodiments, the main gate electrode 148a and the third sub-gate electrode 146a may have a shape connected to each other by the connection gate electrode 147a. That is, the main gate electrode 148a, the connection gate electrode 147a, and the third sub-gate electrode 146a may have a shape integrally connected to one another in a cross-section perpendicular to the second horizontal direction (the Y direction).

The gate insulating layers 130a may be arranged between the gate electrode 140a and the active region FA, between the gate electrode 140a and the device isolation layer 110, and between the gate electrode 140a and each of the first to third nanosheets 152a, 154a, and 156a. The gate insulating layer 130a may include a first gate insulating layer 132 arranged between the first sub-gate electrode 142a and the active region FA and between each of the first sub-gate electrode 142a and the second sub-gate electrode 144a and each of the first nanosheet 152a and the second nanosheet 154a; and a second gate insulating layer 134 arranged between each of the main gate electrode 148a, the connection gate electrode 147a, and the third sub-gate electrode 146a and each of the second nanosheet 154a and the third nanosheet 156a.

The gate spacer 160a may be arranged on both sidewalls of the main gate electrode 148a and both sidewalls of the gate capping layer 170. The gate spacer 160a may be apart from the main gate electrode 148a with the gate insulating layer 130a therebetween. The gate spacer 160a may include a first gate spacer 162 far from the device isolation layer 110 in the first horizontal direction (the X direction) and a second gate spacer 164 close to the device isolation layer 110 in the first horizontal direction (the X direction). In embodiments, a bottom surface of the first gate spacer 162 may be at a higher vertical level than a bottom surface of the second gate spacer 164. In embodiments, the bottom surface of the first gate spacer 162 may contact a top surface of the third nanosheet 156a and the bottom surface of the second gate spacer 164 may contact a top surface of the second nanosheet 154a.

Internal spacers 120 may be between the first to third sub-gate electrodes 142, 144, and 146 and the plurality of source/drain regions SD, between the first to third sub-gate electrodes 142a, 144a, and 146a and the source/drain region SD on one wall of the first gate structure GS1a, and between the first and second sub-gate electrodes 142a and 144a and the device isolation layer 110. That is, in the semiconductor device 200 shown in FIGS. 5 and 6, unlike the semiconductor device 100 shown in FIGS. 1 and 2, the internal spacer 120 may not be between the third sub-gate electrode 146a connected to the main gate electrode 148a and the device isolation layer 110.

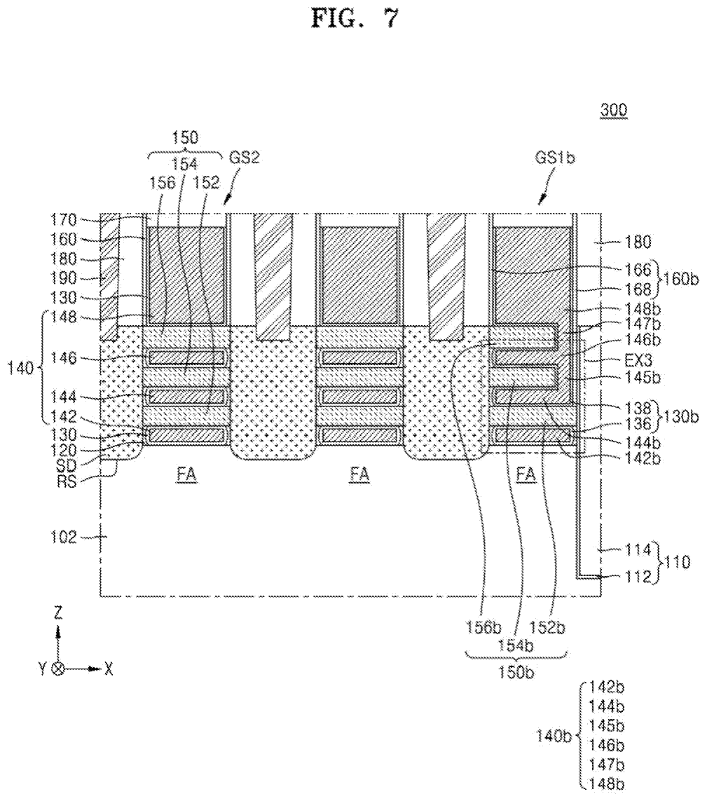

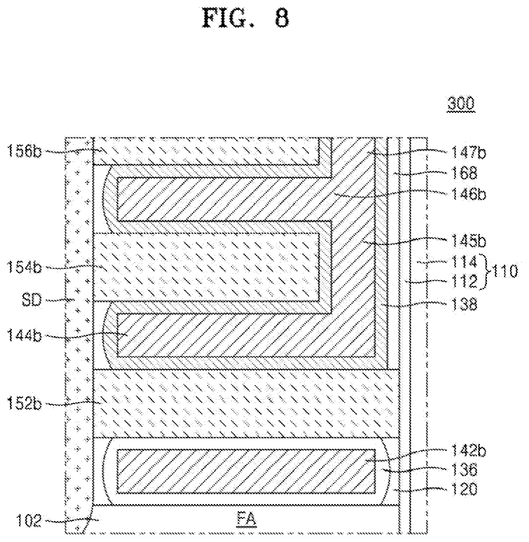

FIG. 7 shows a cross-sectional view of a semiconductor device 300 according to embodiments. FIG. 8 shows an enlarged cross-sectional view of the portion EX3 of FIG. 7. Because a configuration of the semiconductor device 300 shown in FIG. 7 is similar to the configuration of the semiconductor device 100 described with reference to FIGS. 1 and FIG. 2, the differences therebetween are mainly described hereinafter.

Referring to FIGS. 7 and 8, the semiconductor device 300 may include a substrate 102, nanosheet stacks 150b arranged on the substrate 102, first and second gate structures GS1b and GS2 arranged on the substrate 102, a plurality of source/drain regions SD contacting the nanosheet stacks 150b, and source/drain contacts 190 connected to the plurality of source/drain regions SD.

The nanosheet stacks 150b may be apart from top surfaces of a plurality of active regions FA in the vertical direction (the Z direction) perpendicular to the first horizontal direction (the X direction) and the second horizontal direction (the Y direction). First to third nanosheets 152b, 154b, and 156b may be sequentially stacked on the top surface of each of the plurality of active regions FA. In embodiments, in the first horizontal direction (the X direction), a length of the first nanosheet 152b may be greater than a length of each of the second nanosheet 154b and the third nanosheet 156b.

The first gate structure GS1b may include gate insulating layers 130b, a gate electrode 140b, a gate spacer 160b, and a gate capping layer 170.

The gate electrode 140b may include a main gate electrode 148b, first to third sub-gate electrodes 142b, 144b, and 146b, a first connection gate electrode 145b, and a second connection gate electrode 147b. The main gate electrode 148b may cover a top surface of the nanosheet stack 150b and may extend in the second horizontal direction (the Y direction). The first to third sub-gate electrodes 142b, 144b, and 146b may be integrally connected to the main gate electrode 148b and may be arranged among the first to third nanosheets 152b, 154b, and 156b and between the active region FA and the first nanosheet 152b. The first sub-gate electrode 142b may be closest to the top surface of the active region FA, the third sub-gate electrode 146b may be farthest from the top surface of the active region FA, and the second sub-gate electrode 144b may be between the first sub-gate electrode 142b and the third sub-gate electrode 146b.

In embodiments, the main gate electrode 148b, the third sub-gate electrode 146b, and the second sub-gate electrode 144b may have a shape connected to one another by the first connection gate electrode 145b and the second connection gate electrode 147b. That is, the main gate electrode 148b, the third sub-gate electrode 146b, the second sub-gate electrode 144b, the first connection gate electrode 145b, and the second connection gate electrode 147b may have a shape connected to one another in a cross-section perpendicular to the second horizontal direction (the Y direction).

The gate insulating layers 130b may be arranged between the gate electrode 140b and the active region FA, between the gate electrode 140b and the device isolation layer 110, and between the gate electrode 140b and each of the first to third nanosheets 152b, 154b, and 156b. The gate insulating layer 130b may include a first gate insulating layer 136 arranged between the first sub-gate electrode 142b and the active region FA and between the first sub-gate electrode 142b and the first nanosheet 152b and a second gate insulating layer 138 arranged between each of the main gate electrode 148b, the first connection gate electrode 145b, the second connection gate electrode 147b, and the third sub-gate electrode 146b and each of the first to third nanosheets 152b, 154b, and 156b.

The gate spacer 160b may be arranged on both sidewalls of the main gate electrode 148b and both sidewalls of the gate capping layer 170. The gate spacer 160b may be apart from the main gate electrode 148b with the gate insulating layer 130b therebetween. The gate spacer 160b may include a first gate spacer 166 far from the device isolation layer 110 in the first horizontal direction (the X direction) and a second gate spacer 168 close to the device isolation layer 110 in the first horizontal direction (the X direction). In embodiments, a bottom surface of the first gate spacer 166 may be at a higher vertical level than a bottom surface of the second gate spacer 168. In embodiments, the bottom surface of the first gate spacer 166 may contact a top surface of the third nanosheet 156b and the bottom surface of the second gate spacer 168 may contact a top surface of the first nanosheet 152b.

Internal spacers 120 may be between the first to third sub-gate electrodes 142, 144, and 146 and the plurality of source/drain regions SD, between the first to third sub-gate electrodes 142b, 144b, and 146b and the source/drain region SD on one wall of the first gate structure GS1b, and between the first sub-gate electrode 142b and the device isolation layer 110. That is, in the semiconductor device 300 shown in FIGS. 7 and 8, unlike the semiconductor device 100 shown in FIGS. 1 and 2, the internal spacer 120 may not be between the third sub-gate electrode 146b connected to the main gate electrode 148b and the device isolation layer 110 and between the second sub-gate electrode 144b and the device isolation layer 110.

FIGS. 9A to 9J show cross-sectional views of stages in a method of manufacturing a semiconductor device 100, according to embodiments.

Referring to FIG. 9A, the plurality of sacrificial gate layers 140S and the first to third nanosheets 152, 154, and 156 may be alternately stacked on the substrate 102. The plurality of sacrificial gate layers 140S and the first to third nanosheets 152, 154, and 156 may include semiconductor materials having different etching selectivities. In embodiments, the first to third nanosheets 152, 154, and 156 may include Si layers and the plurality of sacrificial gate layers 140S may include SiGe layers.

Referring to FIG. 9B, from the result of FIG. 9A, parts of the substrate 102, the plurality of sacrificial gate layers 140S, and the first to third nanosheets 152, 154, and 156 may be etched to form the active region FA having the fin structure protruding from the substrate 102 in the vertical direction (the Z direction) and the device isolation layer 110 defining the active region FA. A stacked structure of the plurality of sacrificial gate layers 140S and the first to third nanosheets 152, 154, and 156 may remain on the active region FA. Next, a plurality of dummy gate structures DG and a gate spacer 160 covering both sidewalls of each of the plurality of dummy gate structures DG may be formed on the stacked structure of the plurality of sacrificial gate layers 140S and the first to third nanosheets 152, 154, and 156. The plurality of dummy gate structures DG may continuously extend in the second horizontal direction (the Y direction). Each of the plurality of dummy gate structures DG may have a structure in which an oxide layer D112, a dummy gate layer D114, and a dummy capping layer D116 are sequentially stacked. In embodiments, the dummy gate layer D114 may include a polysilicon layer and the dummy capping layer D116 may include a silicon nitride layer.

Referring to FIG. 9C, from the result of FIG. 9B, a part of the active region FA exposed by the plurality of dummy gate structures DG may be etched to form the plurality of recesses RS. In order to form the plurality of recesses RS, the active region FA may be etched by using a dry method, a wet method, or a combination thereof.

Referring to FIG. 9D, from the result of FIG. 9C, the plurality of source/drain regions SD may be formed on the active region FA on both sides of each of the first to third nanosheets 152, 154, and 156. The semiconductor materials may be epitaxially grown from a surface of the active region FA exposed from bottom surfaces of the plurality of recesses RS and the sidewalls of each of the first to third nanosheets 152, 154, and 156 to form the plurality of source/drain regions SD. In embodiments, in order to form the plurality of source/drain regions SD, a low-pressure chemical vapor deposition (LPCVD) process, a selective epitaxial growth (SEG) process, or a cyclic deposition and etching (CDE) process may be performed by using raw materials including elemental semiconductor precursors.

Referring to FIG. 9E, from the result of FIG. 9D, the inter-gate insulating layer 180 covering surfaces of the plurality of source/drain regions SD and surfaces of the gate spacers 160 may be formed. Next, the dummy capping layer D116, the dummy gate layer D114, and the oxide layer D112 may be removed to form a first opening O1 on the nanosheet stack 150.

Referring to FIG. 9F, from the result of FIG. 9E, the plurality of sacrificial gate layers 140S remaining on the active region FA may be removed through the first opening O1 to form the second openings 02. The first opening O1 and the second openings O2 may be connected to one another.

In embodiments, in order to selectively remove the plurality of sacrificial gate layers 140S, a difference in etching selectivity between the first to third nanosheets 152, 154, and 156 and the plurality of sacrificial gate layers 140S may be used. A liquid or gaseous etchant may be used to selectively remove the plurality of sacrificial gate layers 140S. In embodiments, in order to selectively remove the plurality of sacrificial gate layers 140S, a CH₃COOH-based etchant, e.g., an etchant including a mixture of CH₃COOH, HNO₃, and HF, or an etchant including a mixture of CH₃COOH, H₂O₂, and HF may be used.

Referring to FIG. 9G, from the result of FIG. 9F, the internal spacers 120 may be formed in the second openings O2. Therefore, the internal spacers 120 may also be formed in the second openings O2 between the device isolation layer 110 and the source/drain region SD closest to the device isolation layer 110 among the plurality of source/drain regions SD. An atomic layer deposition (ALD) process, a chemical vapor deposition (CVD) process, an oxidation process, or a combination thereof may be used to form the internal spacer 120.

Referring to FIG. 9H, from the result of FIG. 9G, the gate insulating layers 130 covering the exposed surfaces of the first to third nanosheets 152, 154 and 156 and the active region FA may be formed. The gate insulating layer 130 may conformally cover the surface of the gate spacer 160 exposed through the first opening O1.

Referring to FIG. 9I, from the result of FIG. 9H, the gate electrode 140 filling the remaining spaces of the first opening O1 and the second openings O2 may be formed.

Referring to FIG. 9J, from the result of FIG. 91, third openings O3 passing through parts of the inter-gate insulating layer 180 and the plurality of source/drain regions SD may be formed.

Then, from the result of FIG. 9J, the semiconductor device 100 shown in FIGS. 1 and 2 may be manufactured by forming the source/drain contacts 190 filling the third openings O3.

By way of summation and review, the semiconductor device may be capable of preventing a gate insulating layer and a gate electrode from bursting.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate;
an active region protruding from the substrate and extending in a first horizontal direction;
a nanosheet stack spaced apart from a top surface of the active region and having a channel region;
a plurality of gate structures extending in a second horizontal direction perpendicular to the first horizontal direction on the active region and including a plurality of gate electrodes surrounding the nanosheet stack, respectively;
a plurality of source/drain regions arranged on sidewalls of the plurality of gate structures on the active region and contacting the nanosheet stack; and
a device isolation layer passing through the nanosheet stack and extending in a vertical direction perpendicular to the first horizontal direction and the second horizontal direction,
wherein:
the plurality of gate structures include:
a first gate structure in which a source/drain region is arranged on one sidewall of the first gate structure and the device isolation layer is arranged on another sidewall opposite the one sidewall of the first gate structure, and
a second gate structure in which source/drain regions are arranged on both sidewalls of the second gate structure,
the plurality of gate electrodes of the first gate structure include a main gate electrode positioned at an uppermost end and a plurality of sub-gate electrodes in the nanosheet stack, and
an internal spacer is between the device isolation layer and at least one of the plurality of sub-gate electrodes.

2. The semiconductor device as claimed in claim 1, wherein the internal spacer is between the device isolation layer and each of the plurality of sub-gate electrodes.

3. The semiconductor device as claimed in claim 1, wherein the internal spacer has a convexly rounded shape in an outward direction of each of the plurality of sub-gate electrodes.

4. The semiconductor device as claimed in claim 1, wherein the internal spacer includes SiN, SiO₂, SiOC, SiON, SiCN, or SiOCN.

5. The semiconductor device as claimed in claim 1, wherein the plurality of gate electrodes of the first gate structure have a first horizontal direction length in the first horizontal direction, and the plurality of gate electrodes of the second gate structure have a second horizontal direction length greater than the first horizontal direction length in the first horizontal direction.

6. The semiconductor device as claimed in claim 1, wherein the internal spacer is between the first gate structure and the source/drain region arranged on the one sidewall of the first gate structure and between the second gate structure and the source/drain regions arranged on both sidewalls of the second gate structure.

7. The semiconductor device as claimed in claim 6, wherein the internal spacer has a convexly rounded shape in an outward direction of each of the plurality of sub-gate electrodes.

8. A semiconductor device, comprising:
a substrate;
an active region protruding from the substrate and extending in a first horizontal direction;
a nanosheet stack spaced apart from a top surface of the active region and including a plurality of nanosheets functioning as a channel region;
a plurality of gate structures extending in a second horizontal direction perpendicular to the first horizontal direction on the active region and including a plurality of gate electrodes surrounding the nanosheet stack, respectively;
a plurality of source/drain regions arranged on sidewalls of the plurality of gate structures on the active region and contacting the nanosheet stack; and
a device isolation layer passing through the nanosheet stack and extending in a vertical direction perpendicular to the first horizontal direction and the second horizontal direction,
wherein:
the plurality of gate structures include:
a first gate structure in which a source/drain region is arranged on one sidewall and the device isolation layer is arranged on another sidewall opposite the one sidewall, and
a second gate structure in which source/drain regions are arranged on both sidewalls of the second gate structure,
the plurality of gate electrodes of the first gate structure include a main gate electrode positioned at an uppermost end, a plurality of sub-gate electrodes in the nanosheet stack, and a first connection gate electrode connecting the main gate electrode to a third sub-gate electrode positioned at the uppermost end of the plurality of sub-gate electrodes, and
an internal spacer is between the device isolation layer and a first sub-gate electrode positioned at a lowermost end of the plurality of sub-gate electrodes.

9. The semiconductor device as claimed in claim 8, wherein the internal spacer is between the device isolation layer and a second sub-gate electrode arranged between the first sub-gate electrode and the third sub-gate electrode.

10. The semiconductor device as claimed in claim 8, wherein:
the first gate structure includes a first gate spacer arranged on one sidewall far from the device isolation layer between both sidewalls of the main gate electrode, and a second gate spacer arranged on another sidewall close to the device isolation layer between both sidewalls of the main gate electrode, and
a bottom surface of the first gate spacer is at a higher vertical level than a bottom surface of the second gate spacer.

11. The semiconductor device as claimed in claim 10, wherein:
the plurality of nanosheets of the nanosheet stack include a first nanosheet, a second nanosheet, and a third nanosheet sequentially stacked on the active region,
the bottom surface of the first gate spacer contacts a top surface of the third nanosheet, and
the bottom surface of the second gate spacer contacts a top surface of the second nanosheet.

12. The semiconductor device as claimed in claim 8, wherein the internal spacer has a convexly rounded shape in an outward direction of each of the plurality of sub-gate electrodes.

13. The semiconductor device as claimed in claim 8, wherein the internal spacer is between the first gate structure and the source/drain region arranged on the one sidewall of the first gate structure and between the second gate structure and the source/drain regions arranged on both sidewalls of the second gate structure.

14. The semiconductor device as claimed in claim 8, further comprising:
a first gate insulating layer surrounding the first sub-gate electrode and a second sub-gate electrode arranged between the first sub-gate electrode and the third sub-gate electrode; and
a second gate insulating layer surrounding the main gate electrode, the first connection gate electrode, and the third sub-gate electrode,
wherein a part of the second gate insulating layer contacts the device isolation layer.

15. The semiconductor device as claimed in claim 8, wherein:
the plurality of nanosheets of the nanosheet stack include a first nanosheet, a second nanosheet, and a third nanosheet sequentially stacked on the active region, and
a first horizontal direction length of the first nanosheet and a first horizontal direction length of the second nanosheet are greater than a first horizontal direction length of the third nanosheet.

16. The semiconductor device as claimed in claim 8, wherein the plurality of gate electrodes further include a second connection gate electrode connecting a second sub-gate electrode arranged between the first sub-gate electrode and the third sub-gate electrode to the third sub-gate electrode.

17. The semiconductor device as claimed in claim 16, wherein:
the plurality of nanosheets of the nanosheet stack include a first nanosheet, a second nanosheet, and a third nanosheet sequentially stacked on the active region,
the first gate structure includes a first gate spacer arranged on one sidewall far from the device isolation layer between both sidewalls of the main gate electrode, and a second gate spacer arranged on another sidewall close to the device isolation layer between both sidewalls of the main gate electrode,
a bottom surface of the first gate spacer is at a higher vertical level than a bottom surface of the second gate spacer, and
the bottom surface of the second gate spacer contacts a top surface of the first nanosheet.

18. The semiconductor device as claimed in claim 16, further comprising:
a first gate insulating layer surrounding the first sub-gate electrode; and
a second gate insulating layer surrounding the main gate electrode, the second sub-gate electrode, the third sub-gate electrode, the first connection gate electrode, and the second connection gate electrode,
wherein a part of the second gate insulating layer contacts the device isolation layer.

19. The semiconductor device as claimed in claim 16, wherein:
the plurality of nanosheets of the nanosheet stack include a first nanosheet, a second nanosheet, and a third nanosheet sequentially stacked on the active region, and
a first horizontal direction length of the first nanosheet is greater than a first horizontal direction length of the second nanosheet and a first horizontal direction length of the third nanosheet.

20. A semiconductor device, comprising:
a substrate having a fin-type active region extending in a first horizontal direction;
a nanosheet stack apart from a top surface of the active region and including a plurality of nanosheets functioning as a channel region;
a plurality of gate structures extending in a second horizontal direction perpendicular to the first horizontal direction on the active region and including a plurality of gate electrodes surrounding the nanosheet stack, respectively;
a plurality of source/drain regions arranged on sidewalls of the plurality of gate structures on the active region and contacting the nanosheet stack;
a device isolation layer passing through the nanosheet stack and extending in a vertical direction perpendicular to the first horizontal direction and the second horizontal direction;
an inter-gate insulating layer arranged on the plurality of source/drain regions; and
a plurality of source/drain contacts extending through the inter-gate insulating layer and connected to the plurality of source/drain regions, respectively,
wherein:
the plurality of gate structures include:
a first gate structure in which a source/drain region is arranged on one sidewall and the device isolation layer is arranged on another sidewall opposite the one sidewall, and
a second gate structure in which source/drain regions are arranged on both sidewalls of the second gate structure,
the plurality of gate electrodes of the first gate structure include a main gate electrode positioned at an uppermost end and a plurality of sub-gate electrodes in the nanosheet stack, and
an internal spacer is between the device isolation layer and at least one of the plurality of sub-gate electrodes, between the first gate structure and the source/drain region arranged on one sidewall of the first gate structure, and between the second gate structure and the source/drain regions arranged on both sidewalls of the second gate structure.
